(19) United States
(12) Patent Application Publication
(10) Pub. No.: US 2010/0155709 A1
(43) Pub. Date: Jun. 24, 2010

(54) ENCAPSULATION FOR AN ELECTRONIC THIN FILM DEVICE

(75) Inventors: Martinus Jacobus Johannes Hack, Eindhoven (NL); Thomas Nicolaas Maria Bernards, Eindhoven (NL); Peter Van De Weijer, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/600,707

(22) PCT Filed: May 21, 2008
(86) PCT No.: PCT/IB08/51987

§ 371 Date: Nov. 18, 2009

(30) Foreign Application Priority Data
May 24, 2007 (EP) 07108835.5

(51) Int. Cl. H01L 51/52; H01L 51/56

(52) U.S. Cl. 257/40; 438/36; 257/79; 257/E51.022

(57) ABSTRACT

The present invention relates to an encapsulation for an electronic thin film device, comprising a first barrier layer (108), a second barrier layer (112), and a first planarization layer (110′) for reducing the formation of pinholes in a subsequent barrier layer, said first planarization layer (110′) arranged between the first barrier layer (108) and the second barrier layer (112), wherein the first planarization layer (110′) is composed of a first plurality of planarization segment (114) having areas formed between each other, and the encapsulation further comprises a second planarization layer (116) arranged between the second barrier layer (112) and a third barrier layer (120), wherein the second planarization layer (116) is composed of a second plurality of planarization segments (118) arranged to extend over the areas between the first plurality of planarization segments (114), thereby further reducing the number of pinholes providing passageways through the encapsulation. According to the invention, by arranging the barrier layers and the planarization layers in a horizontal multi-layer encapsulation stack, where planarization segments in each of the layers are essentially decoupled from each other and in practice non-interconnecting with each other, it is possible to limit the lateral transportation of water and oxygen through the planarization layer. Instead, if water/oxygen enters the top barrier layer, and eventually a planarization segment, it is contained in the “sphere” of a planarization segment, having a minimized possibility of entering a pinhole in a subsequent barrier layer. The present invention also relates to corresponding method for the formation of an encapsulation for an electronic thin film device.

### FIELD OF THE INVENTION

The present invention relates to an encapsulation for an electronic thin film device, and a corresponding method for the formation of an encapsulation of an electronic thin film device.

### DESCRIPTION OF THE RELATED ART

Exposure of electronic thin-film devices to the ambient atmosphere results in a reduction of the practical lifetime of the device. In case of organic LEDs (both small molecule and polymer LEDs), the most pronounced failure as a result of this interaction is the formation of black spots in the electroluminescence. Water from the ambient atmosphere is penetrating through pinholes in the cathode layer. Oxidation of metal at the cathode-polymer interface prevents electron injection from the cathode into the organic layer during operation of the device, thus introducing a local spot without emission, i.e. a black spot in the bright field of the electroluminescence.

Conventionally, the organic LEDs are typically encapsulated in an inert atmosphere, such as nitrogen or argon, with a freestanding cover made of either metal or glass. This adds roughly a factor of two to the device thickness. A getter is arranged in the cavity between the device and the metal or glass lid, intended to absorb water vapour that is produced by the sealing process or desorbed from the glass or is leaking in through the glue that is used as edge seal. For cheap large-area light source this conventional encapsulation cannot be used. The support of the edges will be insufficient, resulting in sagging of the encapsulant. Moreover, the application of the cavity glass or metal with getter is far too expensive. Further, the concept inhibits the possibility for flexible devices.

In order to reduce cost in the manufacturing process, for providing improved reliability, and for making the package thinner and/or lighter and/or mechanically more flexible, the use of direct thin-film encapsulation (TFE) has been proposed. According to the use of direct thin-film encapsulation, and in the example of an OLED device, alternating and repeating layers of a planarization layer and a barrier layer, generally comprises a metal-oxide, a dielectric layer, or any high barrier dielectric or conducting oxide, are formed on top of the active area of the OLED device. The planarization layer, for example in the form of an organic acrylate layer or the like, generally acts as an encapsulation of particulate matter, such as particles, preventing them from inducing pinholes in the subsequent barrier layer. Without an intermediate planarization layer, a pinhole in a first barrier layer would mimic in a directly adjacent second barrier layer, and the pinhole would grow uninterrupted from the bottom to the top of the device, generating the mentioned inactive parts in the active area of the OLED device. The planarization layer also provides a planar surface for the subsequent barrier layer.

An example of an OLED device encapsulated using the TFE methodology described above is disclosed in U.S. Pat. No. 6,911,667, wherein a planarization layer is deposited on top of the whole active area of the OLED device, and thereafter completely covered by a barrier layer. In an embodiment, an increased number of alternated planarization and barrier layer are used, such that the OLED device is further protected.

However, as a barrier layer at present never can be completely free from pinholes, water and oxygen will eventually leak into the active area of the device (i.e. due to a free passageway from the external environment to the active area of the electronic thin film device). This is due to the fact that a planarization layer is highly transparent to water and oxygen, and a planarization layer arranged between two barrier layer will therefore transport water/oxygen from a pinhole in a first barrier layer to a pinhole in a second barrier layer, eventually reaching the active area of the device. In this way only a delay in the formation of black spots is introduced. An increased number of alternating planarization/barrier layers would only provide a longer “labyrinth” pathway for the water/oxygen to travel. The final delay in black spot growth is considered insufficient with respect to the pursued (shelf) lifetime of the devices. Furthermore, an increase of thickness of the barrier layer does not result in a decrease of the number of uncovered pinholes, as the pinholes continue to grow all through the barrier layer.

### OBJECT OF THE INVENTION

There is therefore a need for an improved encapsulation for an electronic thin film device, and more specifically an encapsulation that has been adapted such that the prior art problems with water/oxygen leakage/pinholes are minimized.

### SUMMARY OF THE INVENTION

According to an aspect of the invention, the above object is met by an encapsulation for an electronic thin film device, comprising a first barrier layer, a second barrier layer, and a first planarization layer for reducing the formation of pinholes in a subsequent barrier layer, said first planarization layer arranged between the first barrier layer and the second barrier layer, wherein the first planarization layer is composed of a first plurality of planarization segment having areas formed between each other, and the encapsulation further comprises a second planarization layer arranged between the second barrier layer and a third barrier layer, wherein the second planarization layer is composed of a second plurality of planarization segments arranged to extend over the areas between the first plurality of planarization segments, thereby further reducing the number of pinholes providing passageways through the encapsulation.

In a prior art electronic thin film device, a horizontal multi-layer encapsulation stack, formed of a continuous planarization layer arranged between a first and a continuous second barrier layer, is arranged to cover the whole electronic thin film device. Due to the characteristics of the planarization layer, water/oxygen entering through a pinhole in the first barrier layer will be transported through the planarization layer and into a pinhole of the second barrier layer, eventually partly destroying the electronic thin film device.

However, according to the invention, by arranging the barrier layers and the planarization layers in a horizontal multi-layer encapsulation stack, where planarization segments in each of the layers are essentially decoupled from each other and in practice non-interconnecting with each other, it is possible to limit the lateral transportation of water and oxygen through the planarization layer. Instead, if water/oxygen enters the top barrier layer, and eventually a planarization segment, it is contained in the “sphere” of a planarization segment, having a minimized possibility of entering a pinhole in a subsequent barrier layer. Other advantages that follows using direct thin-film encapsulation includes, as mentioned above, thinner and/or lighter and/or mechanically more flexible packages.

Even though the first and the second pluralities of planarization segments are said to be decoupled from each other, the skilled addressee understands that depending on the manufacturing method used for forming the planarization segments, it might be necessary to at least partly interconnect the planarization segments with each other. For example, if applying the planarization segments using an ink-jet process, “leakage” could provide microscopic interconnections between the planarization segments. However, the interconnection should preferably be kept at a minimum such that water/oxygen actually entering a planarization segment “sphere” is contained in that sphere.

Furthermore, even though only two planarization layers comprising planarization segments are discussed, it would of course be possible to use more than two planarization layers each comprising pluralities of planarization segments. Also, the number of planarization segments in two different planarization layers can be either the same or different, and this can instead depend on the manufacturing process used.

Preferably, the electronic thin film device comprises a substrate and an active layer formed on the substrate, and the first barrier layer is formed on top of the active layer. That is, in a preferred embodiment, the encapsulation according to the present invention is arranged directly on top of the active area of the electronic thin film device. However, in some embodiments the encapsulation can be “pre-fabricated” and thereafter arranged on top of the active area of the electronic thin film device. Furthermore, it might also be possible to arrange an intermediate layer between the encapsulation according to the present invention and the active area of the electronic thin film device.

To minimize the possible contamination of the active area, i.e. the chance that the lower and upper barrier encapsulating/covering a segment contains a pinhole, the planarization segments should be kept as small as possible, and in a preferred embodiment of the present invention, the width of a planarization segment is less than 10 μm. However, even though 10 μm at present might be seen as a relatively small width for a planarization segment, in future, even smaller sizes might be contemplated. As understood by the skilled addressee, the width might in some cases also be larger than 10 μm. Furthermore, it is not necessary that a planarization segment is a perfect square, instead, a planarization segment might be formed as an outstretched strip, an ellipse, a circle, or any other different form.

In an embodiment of the present invention, the active area comprises a light-emitting layer, an anode and a cathode, thereby forming a light-emitting diode (LED). Such an LED can for example be a small molecule light-emitting device (OLED) or a polymeric light-emitting diode (PLED), or similar. As mentioned earlier, the proper encapsulation of an OLED device is extremely important for reaching a high manufacturing yield and long lifetime of the device. In a OLED/PLED device, if water/oxygen is to come in contact with the cathode (through particle induced pinholes in the device), the interaction will result in inactive parts (black spots) in the OLED/PLED. These spots are perfect spheres, and the area grows linearly in time.

Therefore, by using an encapsulation according to the present invention for the encapsulation of a light-emitting diode, the absence of water/oxygen in the pinholes in the cathode, which are on the sub-micron scale, will therefore not result in the formation of defects that are visible by the naked eye. Furthermore, the presence of pinholes will not result in a reduction of the intrinsic lifetime of the light-emitting device by an early failure that corresponds to the rejection of a device on basis of the occurrence of a black spot.

Preferably, at least one of the barrier layers is formed by a Silicon Nitride (SiN) layer. One single barrier layer formed using Silicon Nitride generally covers 90-99% of the particles/pinholes, and the oxygen/water barrier properties of SiN is good enough to prevent water/oxygen to penetrate through the SiN barrier layer for many 10,000's of hours. However, the remaining 1-10% uncovered pinholes are the problem, and therefore, use of the decoupled planarization segments according to the present invention provides a promising solution to the prior art water/oxygen problematic pinhole induced pathways to the active area of the electronic device. Other barrier materials are also contemplated, however, to provide adequate barrier properties, the water penetration rate for a barrier layer should preferably be at approximately one microgram/m²/day. However, the water penetration rate can range from 5 to 0.1 microgram/m²/day. According to a further aspect of the invention, there is provided a method for the formation of an encapsulation for an electronic thin film device, comprising the steps of forming a first barrier layer, arranging a first planarization layer on top of the first barrier layer, the first planarization layer provided for reducing the formation of pinholes in a subsequent barrier layer, and forming a second barrier layer on top of the first planarization layer, wherein the first planarization layer is composed of a first plurality of planarization segment having areas formed between each other, wherein the method further comprises the steps of arranging a second planarization layer on top of the second barrier layer, and forming a third barrier layer on top of the second planarization layer, wherein the second planarization layer is composed of a second plurality of planarization segments arranged to extend over the areas between the first plurality of planarization segments, thereby further reducing the number of pinholes providing passageways through the encapsulation.

This aspect of the invention provides similar advantages as according to the above discussed encapsulation for an electronic thin film device, including increased lifetime at the same time as the number of defects in the form of pinhole induced inactive parts in the electronic thin film device are reduced.

The different barrier layers and the different planarization layers comprising pluralities of planarization segments can be formed/arranged using different methods known in the art. These methods includes, for example in relation to a barrier layer formed using silicon nitride, a chemical vapor deposition (CVD) method, or one of its variants, such as plasma-enhanced chemical vapor deposition (PECVD). The planarization segments can be arranged/formed using similar method, or methods including conventional ink-jet “printing”, photolithography and dry etching. However, different methods, present and future, can be contemplated and are within the scope of the present invention.

### BRIEF DESCRIPTION OF THE DRAWINGS

These and other aspects of the present invention will now be described in more detail, with reference to the appended drawings showing currently preferred embodiments of the invention, in which:

FIG. 1a is a block diagram illustrating an electronic thin film device encapsulated using a prior art method, and figure lb is a block diagram illustrating an electronic thin film device encapsulated in accordance with an embodiment of the present invention; and

FIG. 2 is a flow chart illustrating the fundamental steps of a method according an embodiment of the present invention for the encapsulation of an electronic thin film device.

### DETAILED DESCRIPTION OF CURRENTLY PREFERRED EMBODIMENTS

The present invention will now be described more fully hereinafter with reference to the accompanying drawings, in which currently preferred embodiments of the invention are shown. This invention may, however, be embodied in many different forms and should not be construed as limited to the embodiments set forth herein; rather, theses embodiment are provided for thoroughness and completeness, and fully convey the scope of the invention to the skilled addressee. Like reference characters refer to like elements throughout.

Referring now to the drawings and to figure la in particular, there is depicted a section of an electronic thin film device, in the present example an organic light emitting device (OLED), encapsulated using a prior art encapsulation. The OLED device comprises a transparent substrate 100, a first transparent electrode layer 102 formed on top of the substrate, a layer of emissive organic polymer material 104, and a second electrode layer 106 formed on top of the organic layer 104. Preferably, the first electrode layer 102, an anode, can for example be made of ITO or the like, and the second electrode layer 106, a cathode, can for example be made of a metal such as MgAg or BaAl. On top of the cathode 106 there is formed a first barrier layer 108, for example made of Silicon Nitride. A planarization layer 110 is deposited on top of the first barrier layer 108, on top of which a second barrier layer 112 is formed. The planarization layer 110, for example in the form of an organic acrylate or the like, acts as an encapsulation of particulate matter, such as particles, preventing them from inducing pinholes in the subsequent barrier layer. The planarization layer 110 also provides a planar surface for the subsequent barrier layer.

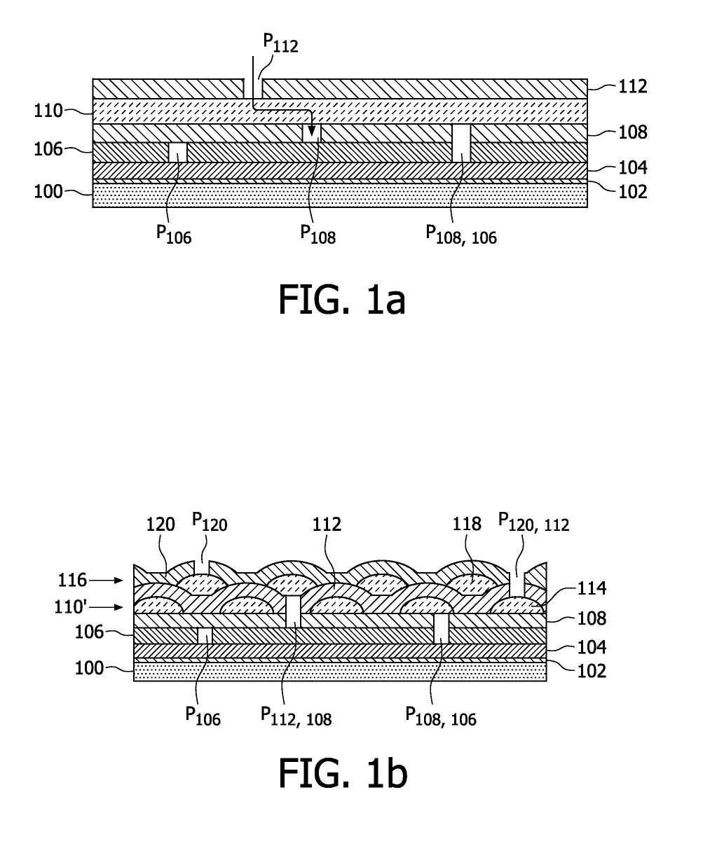

As the second (top) barrier layer 112 comprises pinholes P₁₁₂, water and oxygen will leak into the cathode 106 of the device (illustrated by the arrow). This is due to the fact that the planarization layer 110 is highly transparent to water and oxygen. Thus, the planarization layer 110 will transport water/oxygen from a pinhole P₁₁₂ in the second (top) barrier layer 112 to a pinhole P₁₀₈ in the first barrier layer 108, eventually reaching the cathode 106 of the device. As soon as water/oxygen reaches a pinhole in the cathode 106 of the electronic thin film device, there will be a formation of black spots in the electroluminescence of the OLED. That is due to the fact that oxidation of metal at the cathode-organic polymer interface prevents electron injection from the cathode into the organic layer 104 during operation of the OLED device. As can be seen in FIG. 1a, the different layers comprises a plurality of pinholes P₁₀₆, P₁₀₈, P_{108 106}, and P₁₁₂.

However, the problem with black spots in the electroluminescence of the OLED is handled by the encapsulation according to the present invention. In FIG. 1b, an electronic thin film device, in the present embodiment also an organic light-emitting device, has been encapsulated using an encapsulation according to the present invention. As in FIG. 1a, the OLED comprises a transparent substrate 100, a first transparent electrode layer 102 formed on top of the substrate (e.g. of glass, plastic, or similar), a layer of organic emissive polymer material 104, and a second electrode layer 106 formed on top of the organic layer 104. The multi-layer encapsulation stack according to the present invention is formed on top of the second electrode layer 106, comprising a first barrier layer 108, a first plurality of planarization segments 114 laterally separated from each other, such that areas are formed between each of the planarization segments, and together forming a first planarization layer 110′, a second barrier layer 112 encapsulating/covering the first plurality of planarization segments 114, a second plurality of planarization segments 118 laterally separated from each other, such that areas are formed between each of the planarization segments, and together forming a second planarization layer 116, and a third barrier layer 120 encapsulating/covering the second plurality of planarization segments 118. Similar materials are used as in FIG. 1a. The order of the mentioned multi-layer encapsulation stack according to the present embodiment is from the bottom to the top from a perspective where the first plurality of planarization segments 114 are arranged on top of the second electrode layer 106.

Preferably, the first plurality of planarization segments 114 are selected to have a width of approximately 10 μm and the areas formed between these planarization segments 114 are selected to be somewhat less, such that the second plurality of planarization segments 118 in the second planarization layer 116, having a similar width of approximately 10 μm, are overlapping with the first plurality of planarization segments 114 in the first planarization layer 110′. Thereby, the overall width of the active area is covered by a full planarization layer. Based on this disclosure, the skilled addressee understands that the size of the planarization segments should be kept at a minimum, and thus the planarization segments can have a smaller size than 10 μm. However, they can also be larger, and as mentioned earlier, they can have different sizes in different planarization layers, possibly resulting in different number of planarization segments in the different planarization layers. Furthermore, it is possible to include one or more extra intermediate layer(s) between the cathode 106 and the multi-layer encapsulation stack, and also, or instead, pre-fabricated the multi-layer encapsulation stack and thereafter arranged it on top of the cathode layer 106. The multi-layer encapsulation stack can also, or instead, in another embodiment of the present invention include more than two planarization layers 110′, 116 and three barrier layers 108, 112, 120, e.g. three planarization layers and four barrier layers. In any way, if water/oxygen enters a pinhole P₁₂₀, P_{120, 112} in the top (third) barrier layer 120, and eventually a planarization segment 118, it is contained in the “sphere” of that planarization segment 118, having a minimized possibility of entering a pinhole P_{112, 108} in the barrier layer 108 closest to the cathode layer 106. As can be seen in FIG. 1b, the different layers comprises a plurality of pinholes (P₁₀₆, P_{108, 106}, P_{112, 108}, P₁₂₀, and P_{120, 112}).

During operation of the OLED device in FIGS. 1a and 1b, the OLED device is provided with a voltage differential across the electrodes 102, 106 by an external power supply (not shown). The voltage differential between these electrodes 102, 106 causes a current to flow through the organic emissive material layer 104 causing the emissive layer 104 to emit light out through the transparent electrode 102 and the transparent substrate 100.

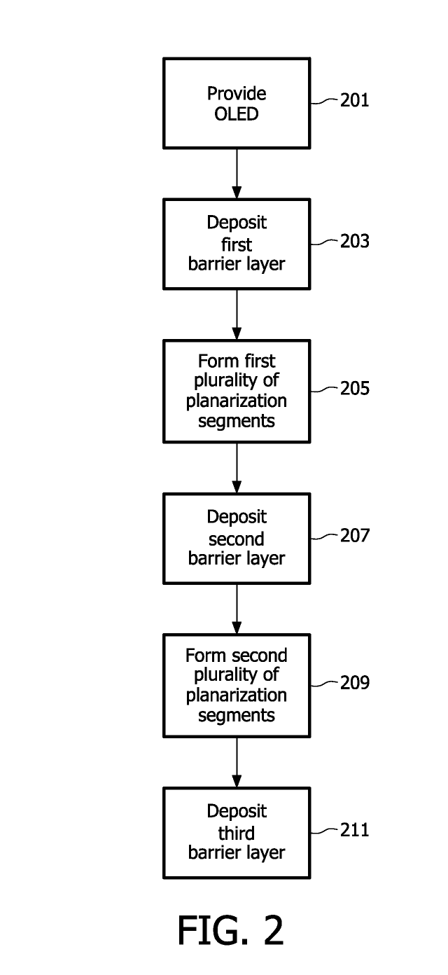

Turning now to FIG. 2, which is a flow chart illustrates the fundamental steps of a method according an embodiment of the present invention, for the encapsulation of an electronic thin film device, such as the OLED device in FIG. 1b.

Initially, in step 201 an electronic thin film device, such as an OLED device, is provided, the OLED device comprising a substrate, a first transparent substrate, a first transparent electrode layer formed on top of the substrate and a layer of emissive organic polymer material formed between the first electrode layer and a second electrode layer.

In step 203, a first barrier layer, preferably in the form of an SiN layer, is deposited on top of the second electrode. The deposition of the SiN barrier layer is preferably done using Plasma enhanced chemical vapor deposition (PECVD). However, other method, present and future, known and developed in the art, can be used for this purpose. The PECVD process requires a shadow mask to define the total area to be encapsulated.

In step 205, a first plurality of planarization segments are formed on top of the first barrier layer (i.e. thereby forming the first planarization layer). Preferably, the planarization segments are formed on top of the first barrier layer using inkjet printing, which is an intrinsically local deposition technique that is capable of creating local structures in the μm range. As the planarization segments are laterally separated and decoupled from each other, small areas are formed between the planarization segments. The width of the planarization segments are preferably in the range of 10 μm, and the areas between the planarization segments are some what smaller than that. As can be seen from FIG. 1b, the planarization segments are not perfect rectangles, instead, the inkjet printing technique will form the planarization segments as “droplets”. The skilled addressee however understands that the droplet appearance is not necessary for the invention, and other forms and methods for forming the planarization segments are possible, including photolithography and dry etching.

In step 207, a second barrier layer is deposited on top of the first plurality of planarization segments, such that the first plurality of planarization segments are completely covering and encapsulating between the first and the second barrier layer. The second barrier layer is preferably formed on the planarization segments in a manner similar to the deposition of the first barrier layer in step 203. However, it is not necessary to use a similar method, or not even the same material as in step 203.

In step 209, a second plurality of planarization segments (thereby forming the second planarization layer) are deposited on top of the second barrier layer. The positioning of the second plurality of planarization segments have been slightly shifted such that the droplets, if using an inkjet printing technique, “falls” at positions coinciding with the areas formed between the plurality of planarization segments of the first planarization layer, thereby slightly overlapping with each other. As in relation to step 205, the second plurality of planarization segments can be formed on top of the second barrier layer using different deposition methods.

Finally, in step 211, a third barrier layer is deposited on the second plurality of planarization segments, such that the second plurality of planarization segments are completely covering and encapsulating between the second and the third barrier layer. Similar techniques for deposition can be used as in steps 203 and 207. As mentioned before, if water/oxygen enters the top (third) barrier layer, and eventually a planarization segment of the second planarization layer, it is contained in the “sphere” of that planarization segment, having a minimized possibility of entering a pinhole in the first (bottom) barrier layer closest to the top electrode layer.

It should be noted that the thickness of the different layers (e.g. anode layer, cathode layer, barrier layers, planarization layers/segments) may be selected based on the fabrication method used for manufacturing the encapsulated OLED device. For example, a SiN barrier layer can be selected to have a thickness in the range of a few hundred nm and preferably around 300 nm, and a planarization segment can have a thickness of approximately a few μm, but these thicknesses can of course be more or less as would be apparent to the skilled addressee.

Furthermore, the skilled addressee realizes that the present invention by no means is limited to the preferred embodiments described above. On the contrary, many modifications and variations are possible within the scope of the appended claims. For example, even though the encapsulation has been described as being deposited sequentially on top of the active area of the electronic thin film device, the encapsulation can be pre-fabricated and thereafter arranged on top of the electronic thin film device. Also, the barrier and planarization layer can be optically transparent, and therefore, the present invention is not limited to so-called bottom emitters. If a transparent cathode is applied, the resulting transparent device can be encapsulated with the encapsulation stack according to the present invention without losing its functionality. Obviously, the stack can also be applied to so-called top-emitting devices, having a transparent cathode and a non-transparent anode.

In conclusion, it is according to the present invention possible to provide an encapsulation for an electronic thin film device that has been adapted such that the pinholes in barrier layers, in conjunction with a water/oxygen transparent planarization layer, will not provide passageways for water and oxygen to leak into an active part of an electronic thin film device. In the example of an LED, pinholes in the cathode, which are on the sub-micron scale, will not result in the formation of defects that are visible by the naked eye. Therefore, the presence of pinholes will not result in a reduction of the intrinsic lifetime of the device by an early failure that corresponds to the rejection of a device on basis of the occurrence of a black spot.

1. An encapsulation for an electronic thin film device, comprising:
a first barrier layer;
a second barrier layer; and
a first planarization layer (110′) for reducing the formation of pinholes in a subsequent barrier layer, said first planarization layer arranged between the first barrier layer and the second barrier layer;
wherein the first planarization layer (110′) comprises a first plurality of planarization segments having areas formed between each other, and that the encapsulation further comprises a second planarization layer arranged between the second barrier layer and a third barrier layer, wherein the second planarization layer comprises a second plurality of planarization segments arranged to extend over the areas between the first plurality of planarization segments, thereby further reducing the number of pinholes providing passageways through the encapsulation, and
wherein the width of each of said planarization segments is less than 10 μm.

2. Encapsulation according to claim 1, wherein the electronic thin film device comprises a substrate and an active layer formed on the substrate, and the first barrier layer is formed on top of the active layer.

3. (canceled)

4. Encapsulation according to claim 2, wherein the active layer comprises a light-emitting layer, an anode and a cathode.

5. Encapsulation according to claim 1, wherein the electronic thin film device is an organic light-emitting device (OLED).

6. Encapsulation according to claim 1, wherein at least one of the barrier layers comprises Silicon Nitride (SiN).

7. Encapsulation according to claim 1, wherein at least one of the barrier layers has a water penetration rate at approximately one microgram/m²/day.

8. A method for the formation of an encapsulation for an electronic thin film device, comprising the steps of:
forming a first barrier layer;
arranging a first planarization layer on top of the first barrier layer, the first planarization layer (110′) provided for reducing the formation of pinholes in a subsequent barrier layer; and
forming a second barrier layer on top of the first planarization layer wherein the first planarization layer comprises a first plurality of planarization segments having areas formed between each other,
arranging a second planarization layer on top of the second barrier layer; and
forming a third barrier layer on top of the second planarization layer, wherein the second planarization layer comprises a second plurality of planarization segments arranged to extend over the areas between the first plurality of planarization segments, thereby further reducing the number of pinholes providing passageways through the encapsulation, wherein the width of each of said planarization segments is less than 10 μm.

9. Method according to claim 8, wherein the electronic thin film device comprises a substrate and an active layer formed on the substrate, and the first barrier layer is formed on top of the active layer.

10. (canceled)

11. Method according to claim 9, wherein the active layer comprises a light-emitting layer, an anode and a cathode.

12. An organic light-emitting device (OLED), comprising:
a substrate;
a. multi-layer stack formed on top of the substrate, the multi-layer stack comprising a light-emitting layer, an anode and a cathode; and
an encapsulation according to claim 1, wherein the encapsulation is arranged on top of the multi-layer stack for encapsulating the organic light-emitting device.
